(19) United States
(12) Patent Application Publication
(10) Pub. No.: US 2010/0003606 A1
(43) Pub. Date: Jan. 7, 2010

(54) PROCESS FOR PRODUCING HOLOGRAMS

(75) Inventor: Nicholas John HARDY, Leeds (GB)

Correspondence Address: PRASS LLP, 2661 Riva Road, Bldg. 1000, Suite 1044, ANNAPOLIS, MD, 21401, US

(73) Assignee: VALOR LIMITED, Birmingham (GB)

(21) Appl. No.: 12/392,255

(22) Filed: Feb. 25, 2009

(30) Foreign Application Priority Data
Feb. 25, 2008 (GB) 08 03345.8

(51) Int. Cl. G03F 7/00

(52) U.S. Cl. 430/2

(57) ABSTRACT

In a process for processing a hologram, a holographic image is formed in a photopolymer layer carried on a substrate. A colour tuning film is applied to the opposed photopolymer layer to form a laminate. The temperature of the laminate is raised and is subsequently cooled and is then exposed to a source of curing electromagnetic radiation.

### CROSS-REFERENCE TO RELATED APPLICATIONS

This application claims foreign priority benefits under U.S.C. §119(a)-(d) to UK 0803345.8, filed Feb. 25, 2008, which is hereby incorporated by reference in its entirety.

### BACKGROUND OF THE INVENTION

1. Field of the Invention

The present invention relates to processes for producing holograms and in particular to processes for producing holograms using photopolymer materials.

2. Background Art

The use of photopolymer materials to produce holograms has increased greatly, particularly where holograms are to be produced in large numbers. In particular, the use of photopolymer films, in which a layer of photopolymer material is sandwiched between a flexible plastics substrate and a flexible plastics cover sheet is particularly advantageous since no wet processing is required, in contrast to the older silver halide holograms.

For many applications, for example when the hologram is used as a security label on a credit card, the quality of the visible image is not critical since the content of the hologram is less significant than the fact that a hologram has been applied.

However, the use of photopolymer material in producing holograms has grown to such an extent that the visual appearance of the hologram is becoming significant. An example of this can be found in WO 02/077533 which discloses an apparatus for simulating a solid fuel fire in which a sheet carrying a holographic image of a bed of fuel cooperates with a flame effect means, whereby the flame effect appears to emanate from the holographic image of the fuel bed, resulting in a very realistic effect and allowing the depth of the apparatus to be reduced.

Therefore, it is important in certain applications that the holographic image which can be viewed is as realistic as possible.

It is known in the formation of holographs on photopolymer materials to record the hologram using a master hologram and a laser which causes polymerisation of the photopolymer in accordance with the interference pattern produced. The polymerisation is then fixed, usually by exposure to ultraviolet light and, optionally, a subsequent heating.

### SUMMARY OF THE INVENTION

It is an object of the present invention to provide a process for producing a hologram which allows images of particularly high quality to be formed on photopolymer films.

In accordance with the present invention, a process for producing a hologram comprises forming a holographic image in a photopolymer layer carried on a substrate, applying a colour tuning film to the exposed photopolymer layer to form a laminate, raising the temperature of the laminate and subsequently cooling the laminate and exposing the laminate to a source of curing electromagnetic radiation.

By carrying out the process in the steps as described, in the order described, it has been found that it is possible to mass-produce holograms of consistently high quality and realism.

Preferably, the photopolymer is carried on a flexible substrate.

Preferably, the substrate comprises a continuous web of material. If a web is used, it can be indexed stepwise so that each portion of the web undergoes each of the aforementioned steps sequentially.

In one embodiment the holographic image is formed on a laminated material comprising a base layer, photosensitive layer and a cover layer. Preferably, the cover layer is removed before the colour tuning film is applied. If the colour tuning film has a cover layer, then that should also be removed before the colour tuning film is applied to the laminated material.

The laminate is preferably heated to a temperature from 100° C. to 140° C., more preferably to approximately 110° C.

Preferably, the temperature of the laminate is raised for a period of between 2 minutes and 6 minutes, more preferably for approximately 3.3 minutes.

Preferably, the laminate is moved through an oven in order to raise its temperature.

The laminate is preferably supported as it passes through the oven.

In one embodiment, the laminate passes over one or more rollers as it passes through the oven, and preferably one or more of the rollers is made of metal.

In one embodiment, the curing electromagnetic radiation comprises ultraviolet radiation.

The wavelength of the ultraviolet radiation is preferably from 315 nm to 400 nm, more preferably approximately 350 nm.

The laminate is preferably exposed to ultraviolet radiation for a time between 2 minutes and 6 minutes, more preferably for approximately 3.3 minutes.

Preferably the laminate is secured to a transparent substrate and preferably the laminate thus formed is severed to form individual holographic sheets.

### BRIEF DESCRIPTION OF THE DRAWINGS

By way of example only, a preferred embodiment of the present invention will now be described, with reference to the accompanying drawings, in which:

FIG. 1 is a flow diagram which explains the general principles of the present invention; and

FIG. 2 is a schematic illustration of an embodiment of apparatus which can be used to implement the process of the present invention.

### DETAILED DESCRIPTION OF THE PREFERRED EMBODIMENT

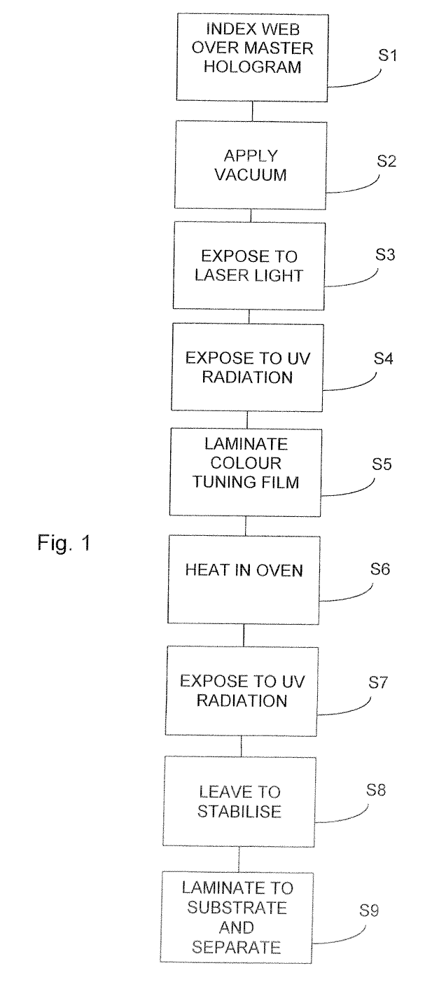

Referring firstly to FIG. 1, the present invention comprises treatment of a photopolymeric material in a series of sequential steps hereafter the term “step” will be abbreviated to “S”).

Briefly, at S1, a continuous web of flexible photopolymer material is indexed so that a portion of the web lies over a master hologram. At S2, a vacuum is applied in a known manner to ensure that the portion of the web in the vicinity of the master is held in close contact with the master. At S3, the portion of the photopolymer film in contact with the master is exposed to laser light at the appropriate wavelength, in a known manner. Typically, this comprises scanning an Argon laser over the entire surface of the area of film in contact with the master. At this point, the holographic image has been formed in the photopolymeric film.

Typically, the photopolymeric film comprises a photopolymeric layer sandwiched between upper and lower layers of flexible polymeric material. If such a film is used, at S4 the film which has been in contact with the master is delaminated and at S5 a colour tuning film is applied to the photopolymer layer and is secured to it, thereby forming a new laminate. The colour tuning film changes the hologram's “playback” wavelength by shifting the wavelength of light. For example, the basic holographic image may be in the green part of the visible spectrum and the colour tuning film may be used to shift the image towards the red end of the spectrum.

At S6, the laminate is heated in an oven at a temperature from 100° C. to 140° C., preferably at 110° C., for a period from 2 to 6 minutes, preferably 3.3 minutes, to increase diffraction efficiency and to change the replay colour of the hologram.

Subsequent to being heated, at S7 the portion of the web is exposed to ultraviolet light typically at a wavelength of from 315 nm to 400 nm, preferably approximately 350 nm, for a period from 2 to 6 minutes, preferably approximately 3.3 minutes.

At S8, the holograms are optionally left to stabilise for approximately one day and at S9 the holographic laminate web is secured to a substantially rigid transparent substrate, which is then separated into individual holographic sheets.

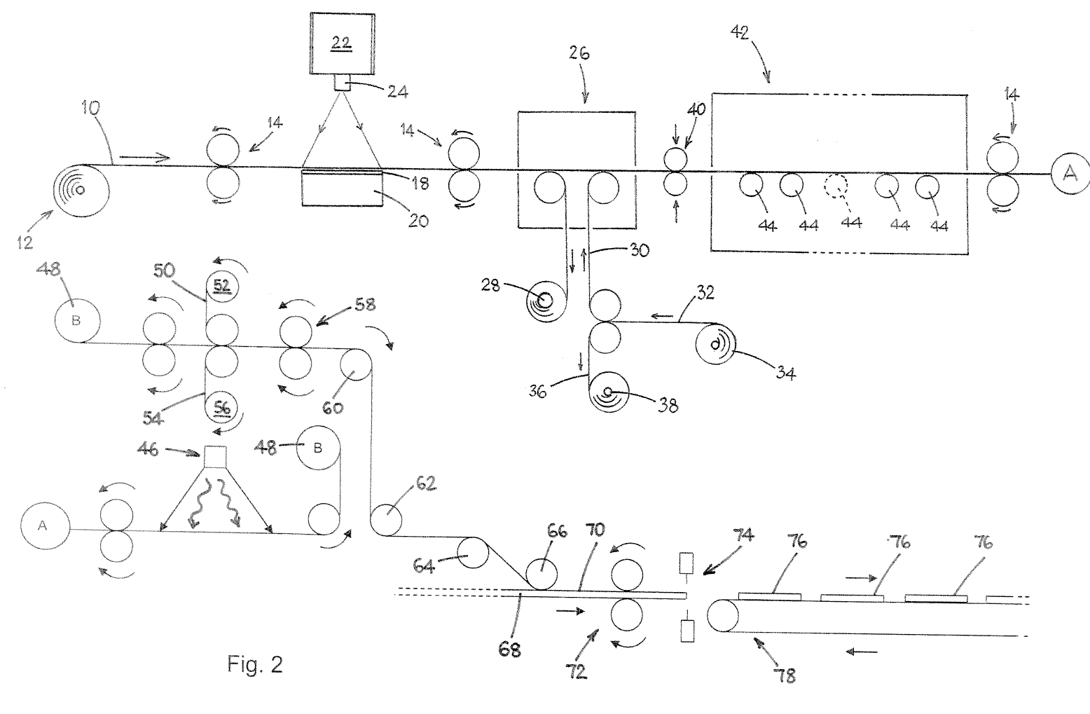

FIG. 2 is a schematic illustration of an apparatus which shows how the process can be implemented.

The apparatus is arranged to feed a continuous web 10 of photopolymer film sequentially through a series of processing steps. The web 10 is unrolled from a roll 12 of the material, a suitable example of material being OmniDex photopolymer film manufactured by E.I. DuPont De Nemours, which comprises a photopolymer layer sandwiched between a flexible polymer base layer and a flexible polymer cover layer. The web is fed stepwise through the various processing stages by means of pairs of opposed driving rollers 14 at various positions along the length of the web (illustrated schematically in the Figure). The rotation of the pairs of driving rollers 14 is synchronised so that all parts of the web are indexed forward at the same time and at the same speed.

The web 10 is indexed so that a portion of the web lies immediately above a master hologram 18, which will normally be formed on a rigid plate. The master hologram 18 is mounted in conjunction with a vacuum device 20 which, when activated, draws the portion of the web 10 immediately above the master into intimate contact with the upper surface of the master plate, to minimise errors in the reproduced hologram on the web, in the known manner. The portion of the web 10 immediately above the master is then exposed to laser light from a laser 22 located above the web, in a known manner. The laser typically scans the entire surface of the portion of the web in contact with the master hologram 18, thereby forming a holographic image on the web. Different types of laser can be used, but an Argon laser has been found to be particularly effective. The laser is scanned across the surface of the web by means of a mirror arrangement illustrated schematically at 24, which may also be arranged to illuminate the web at any one of a number of desired angles. The web 10, which is in the form of a Mylar base sheet, a photopolymer layer and a Mylar cover sheet, is then indexed to a laminator/delaminator 26. A suitable laminator would be an OmniDex laminator manufactured by E.I. DuPont De Nemours and Company, Inc., Wilmington, Del. The cover layer of Mylar is removed from the web 10 is then captured on a driven take-up roller 28 which is synchronised to move at the same time and same speed as the main web 10.

The laminator/delaminator 26 also applies a colour tuning film 30 to the exposed photopolymer layer. The colour tuning film 30 forms one layer of a double-layer web 32 which is fed from a roll 34 of material. The other layer of the web is formed from a sheet 36 polyvinylchloride. One suitable colour tuning film may, for example, be [identify one example of colour tuning film]. However, the polyvinylchloride layer 36 is removed and rolled up on a take-up roller 38 which, again, is driven in synchronicity with the main web 10 of material.

The newly-formed laminate web then passes through a pair of nip rollers 40 which press the colour tuning film firmly against the photopolymer film. The laminate thus formed then passes into an oven 42. It appears to be important that, as the film passes through the oven, it is supported on rollers 44, particularly metal rollers, rather than being allowed to “float” while in the oven. As for the rest of the web, the web is indexed stepwise through the oven.

The oven is maintained at a temperature from 100° C. to 140° C. and is preferably held at temperature of 110° C. The length of the oven is such that the web is heated in the oven for a period from 2 to 6 minutes, preferably approximately 3.3 minutes.

After emerging from the oven, each holographic image is exposed to ultraviolet light from a UV lamp 46 source which preferably emits radiation having a wavelength from 315 nm to 400 nm, preferably 350 nm. The holographic images are exposed to radiation for a period from 2 minutes to 6 minutes and most preferably for 3.3 minutes. After being exposed to the ultraviolet light, the web is collected as a roll 48. The roll 48 which carries the holographic images may then optionally be stored for approximately 24 hours in order to stabilise the images. The web is then subsequently incorporated into a rigid laminated structure using conventional techniques, one of which is described with reference to FIG. 2.

In the laminating procedure illustrated in FIG. 2, a cover sheet 50 of clear self-adhesive polymer dispensed from a roll 52 is laminated to the outer face of the web and a clear double-sided self-adhesive polymer sheet 54 dispensed from a roll 56 is laminated to the inner face of the web. The laminated web is fed through driving rollers 58 and is guided by guide rollers 60, 62, 64, 66 onto a substantially rigid transparent substrate 68 formed from 3 mm thick tinted Perspex (Trade Mark), whose displacement is coordinated with the movement of the web, the two forming a final laminate 70. The final laminate 70 then passes through a further set of drive rollers 72 and then through a guillotine 74 which is coordinated with the stepwise movement of the web and the final laminate 70 and is arranged to separate the holographic images into separate holographic sheets 76, which may then be carried away on a conveyor belt 78, ready for use.

The invention is not restricted to the details of the foregoing embodiment. For example, laminating procedures other than that described may be used. Moreover, the times of the heating and exposure of the web may vary from those described, as may the temperatures and wavelengths used.

What is claimed is:

1. A method for producing a hologram, comprising forming a holographic image in a photopolymer layer carried on a substrate, applying a colour tuning film to the exposed photopolymer layer to form a laminate, raising the temperature of the laminate and subsequently cooling the laminate and exposing it to a source of curing electromagnetic radiation.

2. A method as claimed in claim 1, wherein the photopolymer is carried on a flexible substrate.

3. A method as claimed in claim 2, wherein the substrate comprises a continuous web of material.

4. A method as claimed in claim 3, wherein the web is indexed forward stepwise.

5. A method as claimed in claim 1, wherein the holographic image is formed on a laminated material comprising a base layer, photosensitive layer and a cover layer.

6. A method as claimed in claim 5, wherein the cover layer is removed before the colour tuning film is applied.

7. A method as claimed in claim 1, wherein the laminate is heated to a temperature from 100° C. to 140° C.

8. A method as claimed in claim 7, wherein the laminate is heated to approximately 110° C.

9. A method as claimed in claim 1, wherein the temperature of the laminate is raised for a period from 2 to 6 minutes.

10. A method as claimed in claim 9, wherein the temperature of the laminate is raised for approximately 3.3 minutes.

11. A method as claimed in claim 1, wherein the laminate is moved through an oven in order to raise its temperature.

12. A method as claimed in claim 11, wherein the laminate is supported as it passes through the oven.

13. A method as claimed in claim 12, wherein the laminate passes over one or more rollers as it passes through the oven.

14. A method as claimed in claim 13, wherein one or more of the rollers is made of metal.

15. A method as claimed in claim 1, wherein the curing electromagnetic radiation comprises ultraviolet radiation.

16. A method as claimed in claim 15, wherein the wavelength of the ultraviolet radiation is from 315 nm to 400 nm.

17. A method as claimed in claim 16, wherein the wavelength of the ultraviolet radiation is approximately 350 nm.

18. A method as claimed in claim 15, wherein the laminate is exposed to ultraviolet radiation for a time from 2 to 6 minutes.

19. A method as claimed in claim 18, wherein the laminate is exposed to ultraviolet radiation for approximately 3.3 minutes.

20. A method as claimed in claim 1, wherein the laminate is secured to a substantially rigid, transparent substrate.

21. A method as claimed in claim 3, wherein the laminate is secured to a rigid, substantially transparent substrate to form a final laminate and the final laminate is severed to form individual holographic sheets.
